(19) United States
(12) Patent Application Publication
(10) Pub. No.: US 2022/0200540 A1
(43) Pub. Date: Jun. 23, 2022

(54) MODEL TRAINER FOR DIGITAL PRE-DISTORTER OF POWER AMPLIFIERS

(71) Applicant: ULAK HABERLESME A.S., Cankaya / Ankara (TR)

(72) Inventors: DESDINA KOF, Ankara (TR); ALI ARSAL, Ankara (TR); ALPER SINAV, Ankara (TR); ALI METIN BALCI, Ankara (TR)

(21) Appl. No.: 17/557,907

(22) Filed: Dec. 21, 2021

Related U.S. Application Data
(60) Provisional application No. 63/128,788, filed on Dec. 21, 2020.

(51) Int. Cl. H03F 1/32; H03F 3/24; H04B 1/04

(52) U.S. Cl. CPC H03F 1/3247; H03F 3/245; H03F 2200/451; H04B 2001/0425; H03F 2201/3233; H04B 1/0475

(57) ABSTRACT

The non-linear behavior of power amplifier is linearized using a pre-distorter that is adaptive to changes in the behavior of the power amplifier and uses an artificial neural network. According to embodiments presented here, the pre-distorter's artificial neural network is model-trained from time to time to learn the inverse of the transfer function of the power amplifier by using a second pre-distorter modeling system. The second modeling system determines the parameters of the inverse of the transfer function of the power amplifier using a least square method by using the (un-distorted) output signal samples of the power amplifier. Using the output of the second system as output to train the neural network enables the neural network to more successfully linearize the power amplifier's behavior. Furthermore, the trained artificial neural network as the pre-distorter can be implemented in hardware and presents a small form factor.

### RELATED APPLICATION

This application claims the benefit of provisional application 63/128,788 filed Dec. 21, 2020.

### BACKGROUND OF THE INVENTION

### Field of Invention

The present invention relates generally to an apparatus and method for pre-distorting the input signal of a non-linear system such as a power amplifier to linearize the output signal, and more specifically using a training system for the pre-distorter comprised of an artificial neural network (ANN) model trained by an estimator that uses a regression technique.

### Discussion of Related Art

The 5G cellular networks present some dramatic challenges to both the design of user devices and communication infrastructures since 5G networks target higher than 10 Gbps download speeds. Furthermore, with the usage of millimeter-wave (mm-Wave) spectrum and multiple-input multiple-output (MIMO) antennas, 5G aims at connecting not only user devices but also densely distributed Internet of Things (IoT) and devices of ultra-small latency and ultra-reliable machine to machine type of communications. The broadband modulation for 5G radio frequency (RF) transmitters over 1 GHz requires much higher power efficiency and stringent conformance to linearity from the RF transmitter's power amplifier (PA). Additionally, the usage of massive MIMO antennas with large number of RF front-ends will require unprecedented need for low cost and small form factor, making the design of 5G power amplifier one of the most challenging design issues.

The 5G cellular networks will use a radio technology in the physical layer known as Orthogonal Frequency Division Multiplexing (OFDM). The aim is to offer a much higher bandwidth to each connecting device compared to legacy cellular networks. While presenting many advantages, OFDM brings along significant technical challenges. Two key issues are: high peak-to-average power ratio and large bandwidth the combination of which will lead to severe channel leakage, i.e., inefficiencies, in the frequency domain, which must be remedied.

It is well-known in prior art that the performance of the PA can often dominate the overall transmitter performance since its efficiency dictates the power and heat dissipation of the entire transmitter, see Vereecken et. al., titled “Power consumption in telecommunication networks: overview and reduction strategies.” For enhanced user experience and massive MIMO antennas at mm-Wave frequencies, the 5G system will require large number of PAs to be integrated in a plurality of RF front-ends, making the design of a 5G PA more critical than that of previous generation cellular networks. For any successful commercial 5G deployments, factors such as power usage, linearity, reliability, cost, and form factor of the PA are all extremely important. The embodiments of this invention are about significantly improving the performance of the PA and in turn that of the RF transmitter, while deeming feasible a hardware-based simple PA implementation at a very low cost and small form factor.

Although the Power Amplifier theoretically should behave in a linear fashion (i.e., its function is to simply amplify the input signal), in 5G implementations it behaves non-linearly. This inherent non-linearity of the PA causes the entire RF transmitter to exhibit a non-linear behavior, which in turn results in significant energy efficiency reduction, see Joung et. al., titled, “Spectral Efficiency and Energy Efficiency of OFDM Systems: Impact of Power Amplifiers and Countermeasures.” The PAs that operate in the ‘linear region’ (meaning, the mapping function of output signal to input signal is linear) achieve considerably lower power conversion efficiency. Therefore, 5G prefers to operate in the ‘saturation region’ (meaning, the mapping function of output signal to input signal is non-linear) to increase the overall energy efficiency. However, this mode of PA operation, as a by-product, causes undesirable memory effects, because the output digital signal sample depends not only on the current input digital signal sample but several previous samples as well. This phenomenon causes signal distortions that are classified as ‘interference’ that lead to serious degradation of the quality of the output radio signal, see Cripps et. al., titled, “RF Power Amplifiers for Wireless Communications.” Even when the PA is operating in the linear region it has some small memory effects, but these do not interfere with the main signal samples. However, as the PA approaches to the saturation region the interference increases and these frequency multiples due to memory effects start interfering with the main signal and lowers the quality/linearity of the output signal.

In prior art, the aforementioned undesirable effects of the operation are overcome with the use of a digital pre-distorter (DPD). The DPD is basically inserted in front of the PA (at the input side) to inversely mimic the power amplifier's non-linear transfer function. The system, of combined digital pre distorter (DPD) and PA, leads to an output signal that behaves linearly with respect to the input signal. Doing so, the DPD increases the RF transmitter output signal quality and reduces the power consumption of the PA by allowing linear operations even in the saturation region.

There are mainly three technical problems the DPD must solve together:
(i) Compensation for the non-linear behavior of the PA (by predicting the inverse transfer function of PA),
(ii) Elimination of variable distortion due to memory effects (by modeling the dependence of each output sample to current input sample as well as the past input samples), and
(iii) Providing low complexity and computation stability to allow simple and low-cost hardware-based implementation.

During the last decade, there have been various techniques proposed for the DPD design. Look Up Table (LUT), see Li, F. et. al. titled, “MP/LUT Baseband Digital Predistorter for Wideband Linearization,” and Li, H. et. al. titled, “A Fast Digital Predistortion Algorithm for Radio-Frequency Power Amplifier Linearization with Loop Delay Compensation,” nested LUT, power series, memory polynomial model, Weiner model, and Hammerstein model are just a few popular models used. The LUT model is relatively simple to configure in hardware. However, it suffers from lower accuracy than the other methods. The memory polynomial (MP) models, see Ding, L. et. al., titled, “A Robust Digital Baseband Predistorter Constructed Using Memory Polynomials,” and Kim, J. et. al., titled, “Digital Predistortion of Wideband Signals Based on Power Amplifier Model With Memory,” satisfies both (i) and (ii) above and achieve higher accuracy than LUT. However, it does not satisfy (iii) since it suffers from a highly complex implementation due to needing a large number of arithmetic operations. There are many variants of the polynomial method analyzed in prior art for the design of DPD.

Puri in U.S. Pat. No. 5,164,678 discloses an automatic control system for a power-series based pre-distorter. In this publication, the output signal from the power amplifier and the respective degrees of distortion components generated by a digital pre-distorter are subjected to fast Fourier Transform (FFT) to perform frequency conversion, and the coefficients of the respective degrees are estimated. Also, Suzuki in U.S. Pat. No. 7,418,056 B2 discloses a power-series based pre-distorter with an adaptive controller adjusting the parameters of the power series. However, neither reference accounts for the memory effects of the PA.

In addition to these more traditional methods, recently, different types of Artificial Neural Network (ANN) based techniques have emerged. Theoretically, any neural network is able to learn and imitate the behavior of any nonlinear system according to Universal Approximation Theorem of Neural Networks, see T. Chen et al. titled, “Approximation of continuous functional by neural networks with application to dynamic systems.” Known neural network techniques such as multi-layer perceptron or feed forward neural networks to are not preferred for our problem domain as they are more suitable for memory-less systems. Other machine learning methods such as Recurrent Neural Networks (RNNs), and Convolutional Neural Networks (CNNs), which are able to model the memory effects, are difficult to implement on the hardware as the neural network complexity increases with increasing signal sample size, and as a result, (iii) above can't be satisfied.

There are several machine learning algorithms, inspired by the human brain, known in prior art to train a neural network. Deep learning, for example, is a subset of machine learning techniques where neural networks learn from large amounts of data. Deep learning algorithms perform a task repeatedly and gradually improve the outcome through deep layers that enable a progressive learning.

We call a system “distortion-free” when its output is an exact replica of its input, except for (a) a change of the output's amplitude by a factor called ‘Gain’, and (b) a constant time delay. In other words, a distortion-free system is repeating its input at the output without any modifications, and the only thing the memory effect is doing is introducing a constant phase shift between its input and output. Distortions (modifications to the input signal) are introduced only when the PA is operating in the saturation region. In that nonlinear mode of operation, the phase shift between input and output, instead of being always constant, becomes highly frequency dependent, and therefore, time delay becomes variable. Signal distortion is measured using Error Vector Magnitude (EVM), which provides a comprehensive measure of the quality of the power amplifier. EVM is measured by specialized equipment known in prior art, which first demodulates the received radio signal of the transmitter and produces a stream of so-called I-Q points, which can then be used as a reasonably reliable estimate the ideal transmitted signal in EVM calculation.

The embodiments presented here achieve a higher performance digital pre-distorter (DPD) for the Power Amplifiers in 5G base stations using a lower complexity Artificial Neural Network (ANN) system that can be implemented on hardware and satisfying all three conditions, namely (i), (ii) and (iii) above. A special training model according to an aspect of this invention is devised to design a lower complexity ANN.

Typically, baseband (or digital) pre-distortion is applied to the digital signal samples (viz. digital bit streams), after it is down-converted from radio frequency to baseband frequency. After passing through the pre-distorter and power amplifier, the signal is up-converted to carrier radio frequency using a Digital-to-Analog (D/A) converter. It is an easier and more adaptable pre-distortion technique than pre-distortion directly at those high radio frequencies. Furthermore, baseband pre-distortion has an excellent linearization performance and provides an easy hardware implementation.

The power amplifier characteristics are dynamic and therefore may change due to changes in temperature, device ageing, output antenna matching, bandwidth, traffic conditions, etc. In adaptive pre-distortion, the current condition of the amplifier is factored-in and used while adjusting the pre-distorter parameters by re-training the ANN from time to time. The dynamic nature of the DPD makes the efficiency of ANN training model even more pronounced.

The first embodiment of this invention is an adaptive baseband pre-distorter with a special training system/apparatus that uses a first system of an Artificial Neural Network, ‘ANN’, which is trained efficiently with the output of a second system, the ‘Estimator’ so that the first system matches the behavior of the second system. First, said Estimator estimates the behavior of the inverse of the transfer function of the PA (i.e., that of the DPD) using a regression technique such as Ordinary Least Squares (OLS), Recursive Least Square (RLS) or Least Mean Square (LMS), and by modeling the PA's nonlinearity as well as the memory effects using memory polynomials (MP). First, a sample set from the output of PA is extracted and fed into the Estimator as input samples, wherein Estimator determines the corresponding optimal (linearized) output samples by optimizing its MP parameters. Then, for the training of ANN, we use PA's output samples as the ANN's input samples (because we are modeling the inverse behavior), and the Estimator output samples as the ANN's output samples. After being properly trained, said first system (ANN) behaves like the said second system, the Estimator. The first system, ANN, is trained using a machine-learning technique such as Deep Learning. The resultant ANN model converges rapidly and it is much simpler—as it directly models the Estimator-optimized DPD's model. Note that the first system, ANN, of this invention is easily implementable on hardware, whereas the Estimator is usually far too complex for a hardware implementation. The Estimator requires O(N³) computations for N output samples, whereas ANN's computation complexity is only O(N). When N is large (say >10⁵ samples), the complexity difference becomes much more pronounced. Said trained ANN is then used as the DPD.

Bai in U.S. Pat. No. 8,976,893 B1 discloses a Neural Network based pre-distorter for power amplifiers wherein the memory effects are incorporated by unit delay taps before the input layer of the neural network topology. However, the neural network model training is performed directly using the input and output signals of the power amplifier, and not to conform to an Estimator's model.

Power amplifiers are dynamic nonlinear systems because they concurrently exhibit static nonlinearities as well as dynamic memory effects that change over time due to various reasons. These aspects must be modeled in the second system of the present invention as well as the first system. For the second system, the most comprehensive behavioral model that can be adopted to fully model such systems is the Volterra series. However, Volterra series are typically difficult to manipulate and result in unrealistically large models that are not suitable in practice. The Memory Polynomial (MP) model represents a compact version of the Volterra series and has been widely applied in the behavioral modeling and pre-distortion of power amplifiers having memory effects. Prior art proposes a wide array of structures mainly based on MPs for modeling the pre-distortion, and thus will not be detailed here.

The second system, ANN, converges slowly when it is trained solely with the input and output samples of the PA. Furthermore, the resultant ANN is complex and therefore behaves inefficiently as a live pre-distorter. However, when ANN is trained according to the second system of this invention, it becomes much less complex, it is easily implementable on ASIC-based hardware, the design in cost-efficient, and of small form-factor.

Several Application-Specific Integrated Circuits (ASICs) have emerged that employ strategies such as optimized memory use and the use of lower precision arithmetic to accelerate calculation and increase the throughput of computation, which are ideal for use in ANN implementations. Hardware Neural Networks (HNNs) are in use by many applications and well known in prior art.

We emphasize that the second system, Estimator, is not limited to choosing a specific technique for estimating the behavior of the DPD. Depending on implementation parameters, it may choose to use any regression/curve fitting method such as OLS, LMS, RLS, and any behavioral and memory modeling for the PA known in prior art such as Volterra series, MP, Weiner, Hammerstein, etc.

The second embodiment of this invention is a Training Session Activator, a triggering system that, upon meeting a triggering criterion, re-triggers the training process of ANN using said special training system of the first embodiment. The triggering criterion can be at least (a) measured level of output signal distortion, e.g., the EVM exceeding a specified threshold, (b) significant change in conditions of the RF transmitter (temperature, aging, bandwidth/traffic usage, etc.), or (c) periodic or on-demand model refreshing and updating needed. The Training Session Activator ensures that the ANN is adaptive to the changing conditions of the RF transmitter. The third embodiment of this invention is an Updater System that, upon a re-trained ANN is made available by the first embodiment of this invention, updates the parameters of ANN used as the DPD with the RF transmitter. The Training Session Activator and Updater System are considered as control components of the training system of this invention.

Embodiments of the present invention are an improvement over prior art systems and methods.

### SUMMARY OF THE INVENTION

In one embodiment, the present invention provides a method for adaptive model training of a pre-distorter (PD), the PD configured to pre-distort a power amplifier (PA) input signal of a power amplifier (PA) for a compensation of non-linear behavior and memory effects of the power amplifier, the compensation causing a power amplifier (PA) output signal of the PA to become linearly related to a pre-distorter (PD) input signal and exhibit only a constant delay over time, the method comprising the steps of: (a) identifying an initial topology of an artificial neural network (ANN) model stored in an ANN model trainer, the initial topology comprising: (1) number of neurons in the ANN, (2) number of layers of the ANN, and (3) number of delay taps of the ANN, wherein each delay tap represents one sample delay and a total number of delay taps defining a memory depth of the power amplifier; (b) entering the PA output signal without predistortion as an estimator input signal into an estimator, the estimator configured to use a regression technique and a memory effect modeling technique and generate an estimator output signal corresponding to a best polynomial fit to the estimator input signal; (c) training the ANN model stored in the ANN model trainer using a machine learning algorithm utilizing the PA output signal obtained without predistortion as the ANN model trainer's input and the estimator output signal as the ANN model trainer's output until convergence where the PA output signal obtained with predistortion according to ANN model stored exhibiting a linear relation to the PA input signal with a constant delay, and when convergence is not reached, changing the initial topology and repeating steps (a) through (c) until convergence is reached, and when convergence is reached, mapping parameters corresponding to topology changes as another ANN used in the PD.

In another embodiment, the present invention provides a system comprising: (a) a pre-distorter (PD), the PD configured to pre-distort a power amplifier (PA) input signal of a power amplifier (PA) for a compensation of non-linear behavior and memory effects of the power amplifier, the compensation causing a power amplifier (PA) output signal of the PA to become linearly related to a pre-distorter (PD) input signal and exhibit only a constant delay over time; (b) an ANN model trainer, the ANN model trainer storing an artificial neural network (ANN) model, wherein an initial topology of the ANN model comprising: (1) number of neurons in the ANN, (2) number of layers of the ANN, and (3) number of delay taps of the ANN, wherein each delay tap represents one sample delay and a total number of delay taps defining a memory depth of the power amplifier; wherein the PA output signal without predistortion is input as an estimator input signal into an estimator, the estimator configured to use a regression technique and a memory effect modeling technique and generate an estimator output signal corresponding to a best polynomial fit to the estimator input signal; and the ANN model stored in the ANN model trainer is trained using a machine learning algorithm utilizing the PA output signal obtained without predistortion as the ANN model trainer's input and the estimator output signal as the ANN model trainer's output until convergence where the PA output signal obtained with predistortion according to ANN model stored exhibiting a linear relation to the PA input signal with a constant delay, and when convergence is not reached, the initial topology being changed until convergence is reached, and when convergence is reached, mapping parameters corresponding to topology changes as another ANN used in the PD.

In yet another embodiment, the present invention provides a non-transitory, computer accessible, memory medium storing program instructions for implementing a method for adaptive model training of a pre-distorter (PD), the PD configured to pre-distort a power amplifier (PA) input signal of a power amplifier (PA) for a compensation of non-linear behavior and memory effects of the power amplifier, the compensation causing a power amplifier (PA) output signal of the PA to become linearly related to a pre-distorter (PD) input signal and exhibit only a constant delay over time, wherein one or more programs are stored in the memory and configured to be executed by the one or more processors, the medium comprising: (a) computer readable program identifying an initial topology of an artificial neural network (ANN) model stored in an ANN model trainer, the initial topology comprising: (1) number of neurons in the ANN, (2) number of layers of the ANN, and (3) number of delay taps of the ANN, wherein each delay tap represents one sample delay and a total number of delay taps defining a memory depth of the power amplifier; (b) computer readable program entering the PA output signal without predistortion as an estimator input signal into an estimator, the estimator configured to use a regression technique and a memory effect modeling technique and generate an estimator output signal corresponding to a best polynomial fit to the estimator input signal; and (d) computer readable program training the ANN model stored in the ANN model trainer using a machine learning algorithm utilizing the PA output signal obtained without predistortion as the ANN model trainer's input and the estimator output signal as the ANN model trainer's output until convergence where the PA output signal obtained with predistortion according to ANN model stored exhibiting a linear relation to the PA input signal with a constant delay, and when convergence is not reached, changing the initial topology and repeating steps (a) through (c) until convergence is reached, and when convergence is reached, mapping parameters corresponding to topology changes as another ANN used in the PD.

### BRIEF DESCRIPTION OF THE DRAWINGS

The present disclosure, in accordance with one or more various examples, is described in detail with reference to the following figures. The drawings are provided for purposes of illustration only and merely depict examples of the disclosure. These drawings are provided to facilitate the reader's understanding of the disclosure and should not be considered limiting of the breadth, scope, or applicability of the disclosure. It should be noted that for clarity and ease of illustration these drawings are not necessarily made to scale.

FIGS. 1A and 1B illustrate a simple prior art configuration of a Power Amplifier (PA), and PA's transfer function, respectively.

FIGS. 2A and 2B illustrate two simple prior art general model-learning techniques for a Digital Pre-Distorter.

FIGS. 3A and 3B illustrate a simple configuration of a Neural Network, and the modeling of delay, respectively, according to prior art.

FIG. 4 is an exemplary model of an ANN with delay taps used for memory effects, according to prior art.

FIG. 5 illustrates a high-level block diagram of the computer implementation of the training system, according to the present invention.

FIG. 6 illustrates a simple flowchart showing the first method (training) of the present invention.

FIG. 7 illustrates a simple flowchart showing the second method (control) of the present invention.

### DESCRIPTION OF THE PREFERRED EMBODIMENTS

While this invention is illustrated and described in a preferred embodiment, the invention may be produced in many different configurations. There is depicted in the drawings, and will herein be described in detail, a preferred embodiment of the invention, with the understanding that the present disclosure is to be considered as an exemplification of the principles of the invention and the associated functional specifications for its to construction and is not intended to limit the invention to the embodiment illustrated. Those skilled in the art will envision many other possible variations within the scope of the present invention.

Note that in this description, references to “one embodiment” or “an embodiment” mean that the feature being referred to is included in at least one embodiment of the invention. Further, separate references to “one embodiment” in this description do not necessarily refer to the same embodiment; however, neither are such embodiments mutually exclusive, unless so stated and except as will be readily apparent to those of ordinary skill in the art. Thus, the present invention can include any variety of combinations and/or integrations of the embodiments described herein.

As used herein, a base station (BS), power amplifier (PA) and digital pre-distorter (DPD), D/A Converter, A/D Converter are equipment including hardware and software that communicatively interconnects to other equipment on the network (e.g., other network devices and end systems). Base stations provide the cellular/wireless access to end systems (e.g., devices such as mobile phones, computers, Internet of Things (IoT), etc.).

The power amplifier is a component of the RF transmitter component of the base station that provides the signal amplification at the physical layer of the OSI, and conversion of baseband digitized signals to analog signals at radio frequency (RF) that are emitted through the antenna. The DPD is inserted at the input side of the PA to inversely mimic the behavior of PA so that the combined DPD and PA leads to a linear behavior between the input signal of the DPD and the output signal of the PA. Therefore, the digital pre-distortion implementation is used to increase the efficiency of the signal at the radio frequency transmitter output and to reduce power consumption of the amplifier.

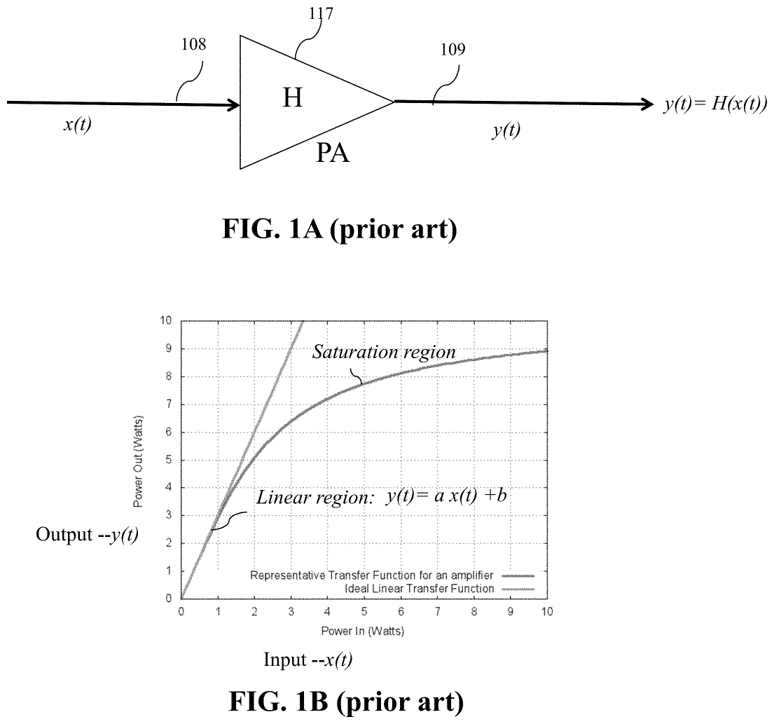

Shown in FIG. 1A is an illustration of a simple Power Amplifier (PA) 117 with input signal of x(t) shown on interface 108 and output signal of y(t) shown on interface 109. The mathematical relationship between the input and output signal is given by a nonlinear transfer function H(.) wherein y(t)=H(x(t)). An exemplary transfer function Ho) is illustrated in FIG. 1B. Note that at lower input signal power levels the transfer function, H(.), is linear, i.e., y(t)=G x(t) where G is a constant that represents the amplifier's ‘gain’. At higher input signal power levels, the transfer function is non-linear. This is the region known as the saturation region.

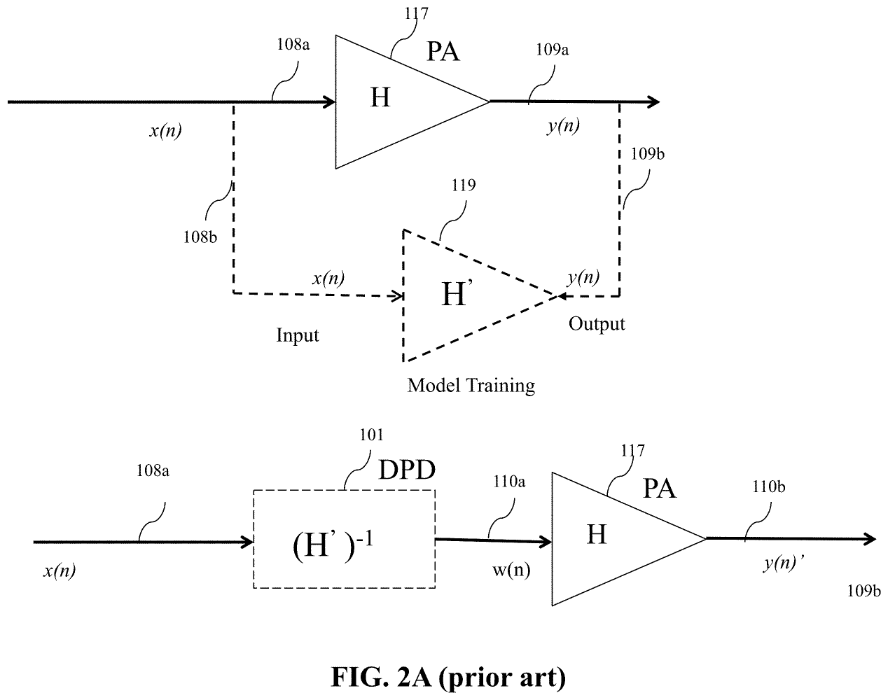

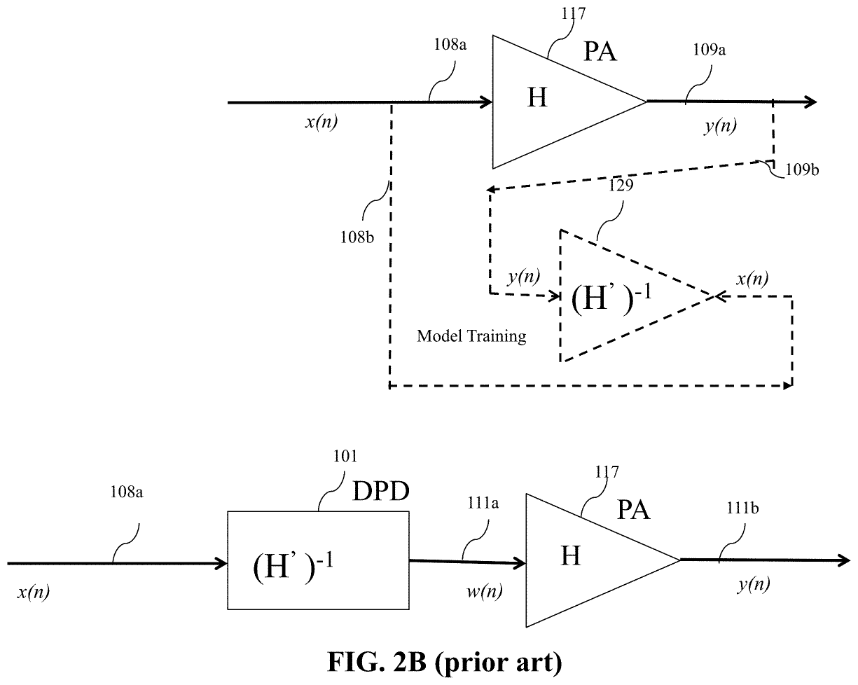

FIGS. 2A and 2B illustrate two different classes of training methods both using directly the PA's input samples and the corresponding output samples for the modeling. FIG. 2A illustrates the model that estimates PA's transfer function, and then uses the inverse of estimated transfer function for DPD. In contrast, FIG. 2B illustrates the model that estimates DPD's transfer function. The figures illustrate a simple configuration with DPD 101 and PA 117. Note that the input of DPD 101 is the input signal x(n) (108a), which is distorted using the inverse of the transfer function of PA 117, (H′)⁻¹, which is determined using, H′, an estimate of H, since the original transfer function is not known. The estimated PA transfer function 119 is obtained by using the input signal 108a and output signal 109a (when DPD is not in the circuit, i.e., using original input of PA). Shown in the figure are 108b and 109b that are the same as 108a and 109a, and used in another system called the ‘model trainer’ using so-called Direct Learning Architecture (DLA) just to determine an estimate of the relationship between the input signal and output signal, and hence the behavior of the PA. Once that behavior is formulated (represented by H′) then the inverse of the behavior is used as the transfer function of DPD to cancel out the non-linearity of PA 117 given that [(H′)⁻¹][H]≈1. Another well-known technique is Indirect Learning Architecture (ILA), a simple diagram of which is shown in FIG. 2B, which directly estimates the inverse of PA's transfer function (i.e., transfer function of DPD) by transposing the input and output samples, i.e. using PA's output as the input, and using PA's input as the output during model training of the DPD. Both DLA and ILA methods are widely used in prior art.

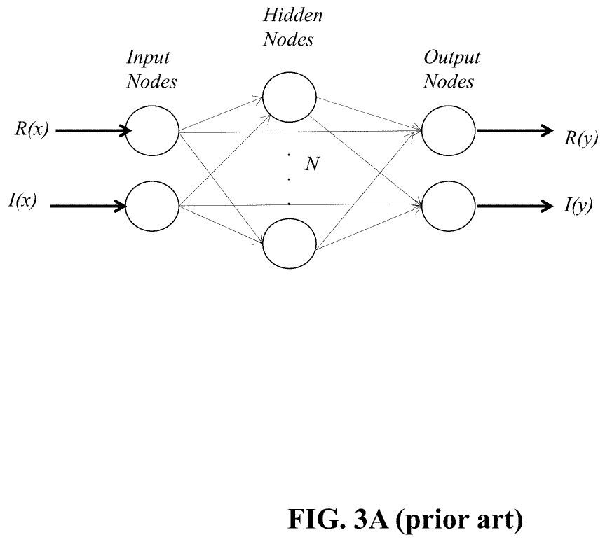

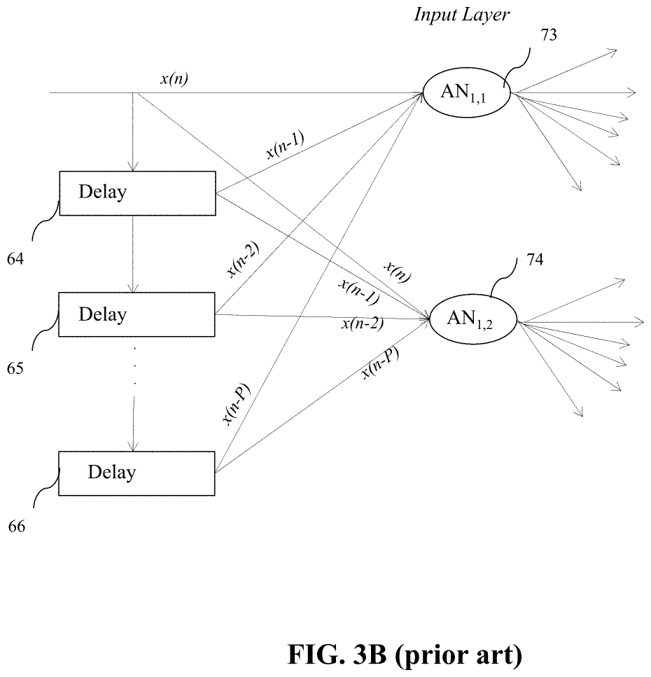

A simple exemplary multi-layer perceptron based Artificial Neural Network (ANN) is depicted in FIG. 3A that has a single input layer, single output layer and a plurality of hidden layers. The nodes (neurons) are distributed to each layer as input nodes, output nodes and hidden layer nodes. Each layer may have different number of nodes. The total number of nodes, the total number of layers, and the number of nodes per layer are determined according to the chosen topology of ANN. Furthermore, the digital signal samples are inserted into the ANN as real and imaginary components, and output is also obtained as real and imaginary components.

Typically, each node i in the ANN performs a functional operation on the received input sample to generate an output sample, e.g., in case of a linear model: Wi x(n)+bi, where Wᵢ and bᵢ are constants associated the i^{th} node. Since each node performs the aforementioned linear operation on its received input sample, a cascade of linear operations occurs when the input sample traverses through the neural network. Let us say that the input sample traverses three layers through node i, node k and node j, then the generated output of these nodes will be [Wᵢx(n)+bᵢ], [Wₖ (Wᵢx(n)+bᵢ)+bₖ], [Wⱼ(Wₖ(Wᵢx(n)+bᵢ)+bₖ) . . . +bⱼ), respectively, assuming each node performs a simple linear operation. Yet, notice that the parameters of the network exhibit a nonlinear function, i.e., Wₖ Wᵢ, Wⱼ WₖWᵢ.

The memory effects can be represented as illustrated in FIG. 3B as delay components (see U.S. Pat. No. 8,976,893 to Bai). Assuming only two input layer nodes, the first delay component 64 feeds x(n−1) as input to both nodes 73 and 74 of the input layer, second delay component 65 feeds x(n−2) as input, and so on. At node 73, the output sample is determined as (W11⁰x(n)+W11¹x(n−1)+ . . . +W11^{P}x(n−P)+b₁₁). Similarly, at node 74, the output sample is (W12⁰x(n)+W12¹x(n−1)+ . . . +W12^{P}x(n−P))+b₁₂). Here W_{1k is layer-}1 node-k's parameter for delay input sample x(n−1). Note that different weights are applied to each delay components in a node.

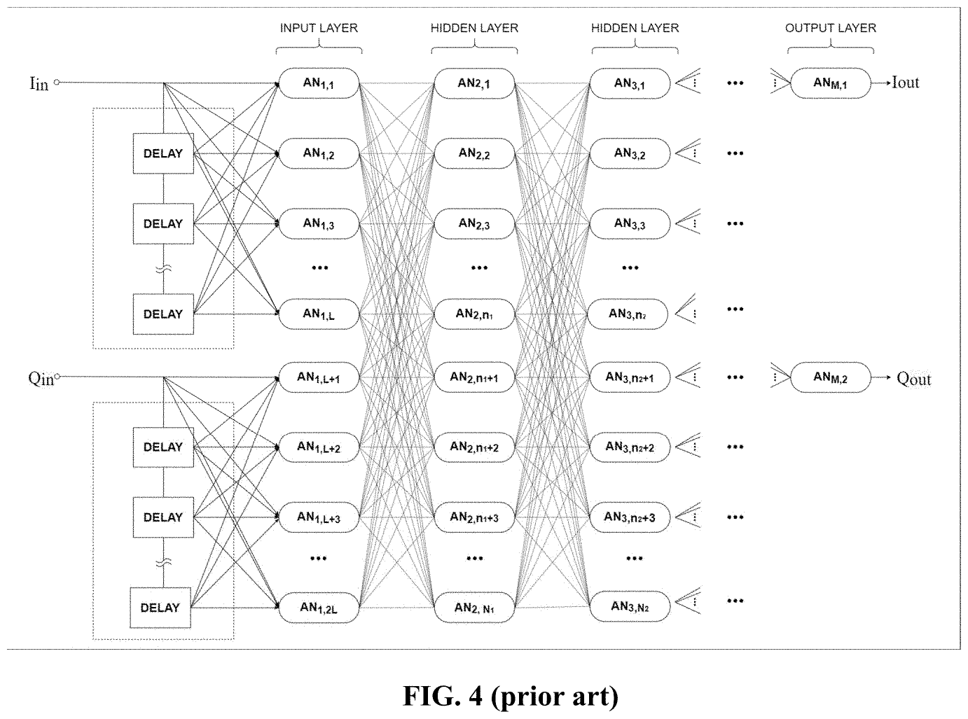

FIG. 4 illustrates another exemplary ANN-based model for the DPD, as a reference. The input layer has artificial neurons/nodes, which are formed in conjunction with the delay tap elements, which directly relate to the memory order of PA 117. Each digital input signal sample's real and imaginary components are labeled as Iᵢₙ and Qᵢₙ, respectively, and processed separately. Shown in the figure are L nodes in the input layer, n₁, n₂, . . . n_{(M-2)} nodes in the hidden layers labeled as layers 2, 3, . . . , (M−1), respectively, and a single node at the output layer for Iᵢₙ samples. Similarly, there are L nodes in the input layer, n₁, n₂, . . . , n_{(M-2)} nodes in the hidden layers labeled as layers 2, 3, . . . , (M−1), respectively, and a single node at the output layer for Qᵢₙ samples. Note that the delayed samples, namely Iᵢₙ (n−1), . . . , Iᵢₙ (n−L), and Qᵢₙ (n−1), . . . , Qᵢₙ (n−L), up to the memory depth L of PA 117 enter each input node first along with Iᵢₙ (n) and Qᵢₙ (n). Thus, there are a total of 2(L+1) input samples that enter the ANN at the input layer. Each AN_{i,j} of the interconnected graph of neurons processes its incoming sample by multiplying it with a constant weighting parameter and by adding a constant bias parameter (and hence modeling a linear transfer function) wherein both sets of parameters are determined using machine learning. The overall processing produces the output sample signal Iₒᵤₜ and Qₒᵤₜ. The neural network model parameters such as the number of nodes per layer, L, n₁, n₂, . . . , 1 and the total number of layers, M (including all input, output and hidden layers), according to FIG. 4, are determined depending upon the performance of ANN with respect to specified metrics, known in prior art. Thus, there may be many different variations of the ANN depending on the choice of topology. Since the topology and training methods of ANN to achieve a desired level of error are detailed in several publications in prior art, it will not be repeated here.

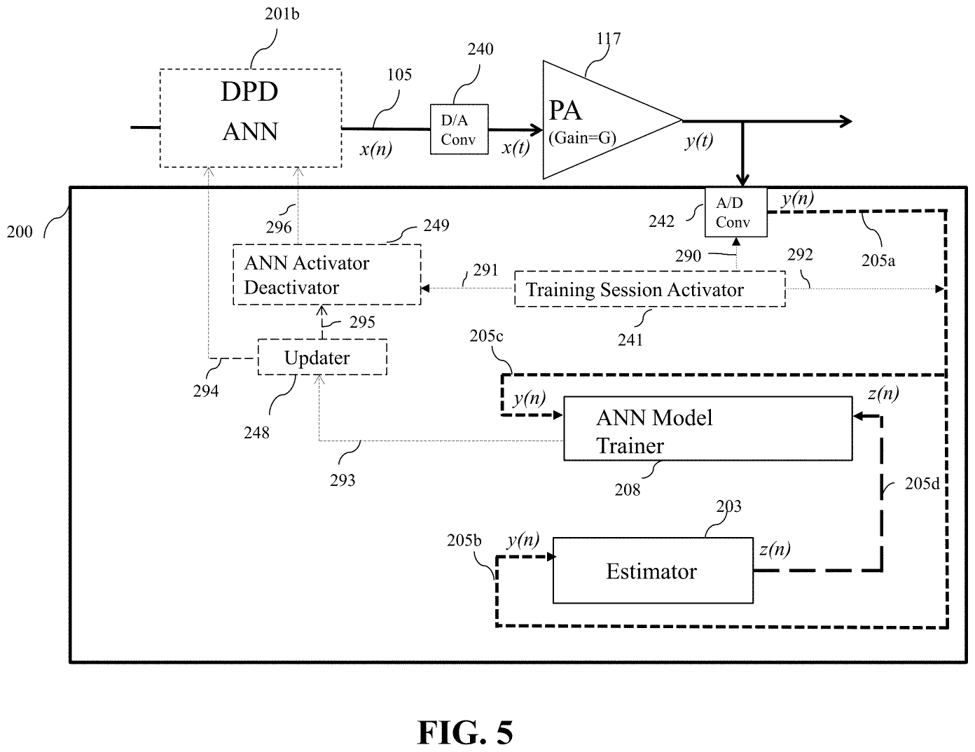

FIG. 5 illustrates Training System 200, the system of the present invention, that has two categories of components:
(a) Training Components that receive and process the output samples of PA to generate input samples, and use these samples for training.
(b) Control Components that coordinate a new training cycle and update the live DPD with the newly learned ANN parameters. Control components ensure that Training System 200 responds to the dynamic nature of PA 117, and can trigger a new cycle of training and update the DPD used in the RF transmitter, accordingly.

The Training Components are:
(i) Estimator 203 that generates the best fitting model for the DPD using PA's output samples as input (viz. ILA model) by accounting for the memory effects.
(ii) ANN Model Trainer 208 that trains the ANN with the input samples, y(n), which correspond to the output sampled of the PA (ILA model), and output samples, z(n), generated by the model of Estimator 203. Doing so, model training is performed to match the best model fit generated by Estimator 203.
(iii) A/D Converter 242 that generates PA 117's digital output samples y(n) from the radio frequency output signal y(t). Such sampling is only performed during an initiation of a new training cycle. N number of samples are obtained for training where N is configurable.

Estimator 203 may, for example, use RLS for estimation, and MP for modeling the pre-distorter. First, y(n) (205b) is fed as input to Estimator 203, which then generates z(n) (205d) as output. Once z(n) is generated, y(n) (205c) is fed as input to ANN Model Trainer 208, and z(n) (205d) is fed as output, and training is performed. Note that 205a, 205b, and 205c have the same sample values. However, 205a is collected y(n) samples and stored in memory. 205b is either 205a, or a subset of y(n), that is fed to Estimator 203 in order to generate corresponding z(n) (205d). 205c is either 205a, or a subset of it, that is fed into ANN Model Trainer 208 pairwise with z(n), after z(n) is produced by Estimator 203.

The Control Components are:
(i) Training Session Activator 241 that triggers the model training process of the system of the present invention based on determined update schedules or upon violation of predefined performance thresholds or conditions.
(ii) Updater 248 that checks to determine if the training has converged (i.e., successfully completed). If yes, it updates the parameters on ANN 201b that is used as the DPD in the RF transmitter. Updater 248 may simply replace the parameters with the new parameters determined after a new cycle of training, or may add and configure more delay taps, nodes and layers, if necessary.
(iii) ANN Activator/Deactivator 249 that (a) deactivates ANN 201b during the beginning of a new cycle of training to collect un-distorted data samples from PA 117's output, and (b) activates ANN 201b after Updater 248 configures new parameters onto ANN 201b to initiate the live operations as DPD.

When Training Session Activator 241 determines to initiate a new training cycle, it must first de-activate ANN 201b through ANN Activator/Deactivator 249, and then start the collection of undistorted output samples of PA 117 at the output of A/D Converter 242. Interfaces 290 through 296 are called control interfaces that are pertinent to coordination of a training cycle, e.g., de-activating ANN 201b before sample collection, sample collection from A/D converter 242, updating ANN 201b parameters according to the results of the new training cycle, and then re-activating ANN 201b to return to normal operations, etc.

According to this invention, various embodiments are generated for a DPD suitable for the 5G base station's RF transmitters with as high as possible performance, but as low as possible complexity and cost. This is achieved using a combination of artificial neural network ANN 201b trained by ANN Model Trainer 208 as the pre-distorter, and Estimator 203 that can accommodate different regression techniques and different algorithms for memory effect modeling and that acts as a modeling agent for ANN for recursive, but extremely fast model training.

Once the model is properly trained using the system of the present invention, DPD (ANN 201b) will distort each input signal sample. More specifically, it distorts the input signal x(n) (105), where n is the sample number, to compensate for the distortion that will be introduced by PA 117, and then the pre distorted signal, which is the output of ANN 201b, becomes the input signal of PA 117 yielding an output signal of y(n). Doing so, the output signal y(n) will contain much fewer distortion elements than the case without ANN 201b.

The recursive least square (RLS) algorithm as Estimator 203 is one of the preferred models for the artificial neural network (ANN) when the learning data set is very large and complex, and the system is fairly dynamic as in the case of Power Amplifiers. A key method of the present invention is training ANN with the output of Estimator 203 to force the ANN to behave according the Estimator's output. There are advantages in incorporating Estimator 203 to the training of the system of the present invention in contrast to training ANN 201b directly with PA's input and output samples, x(n) and y(n), respectively: convergence is really fast, the ANN requires much fewer nodes and it therefore it is more compact. It provides stability and the avoidance of a local minimum during convergence.

According to another aspect of this invention, Estimator 203 incorporates the memory effects of the PA into the modeling algorithm so as to being able to account for the memory effects causing signal distortion due interference up to a certain memory depth, i.e., x(n−1), x(n−2), x(n−3), . . . , x(n−P) where P is the memory depth, as well as the degree of nonlinearity of each memory sample. The teachings of the embodiments here provide a simple analytical framework by which the Least Square method successfully incorporates the dependency of current output sample not only to the current input sample but also to past input samples, and by doing so, it creates a realistic training sample set to ANN 201.

The Least Square method minimizes the difference (or error) between the desirable linear behavior of the combined system of ANN 201b and PA 117 and the nonlinear behavior of the combined system. Using the nomenclature of FIGS. 2A & B, and for the sake of simplicity considering a memory-less system, the desired linear behavior of ANN+PA is:

y(n)=Gx(n) (1)

where G is the PA's gain. In contrast, the actual behavior of ANN+PA at the saturation region is characterized by:

y(n)′=(H′)⁻¹H(x(n)) (2)

Simply incorporating Eq. (1) into (2), we obtain the following:

y(n)′=(H′)⁻¹H(y(n)/G) (3)

In simplest terms, the objective of LS is to minimize the error between y(n)′ and y(n) (meaning making y(n)′ as close as possible to the ideal linear output behavior y(n)):

Min[y′(n)−y(n)]²=Min[(H′)⁻¹H(y(n)/G)−y(n)]² (4)

The solution to (4) is well known in prior art with various recursive/iterative methods.

The problem is far more complicated when there are memory effects, i.e., when y(n) does not only depend on x(n) but also to x(n−1), x(n−2), x(n−3), etc. and each of these prior samples have different degree of non-linearity.

An exemplary Memory Polynomial (MP) algorithm, known in prior art, of Estimator 203 that models the memory effects according to this invention is presented below only as a reference. The output of Estimator 203, z(n), in terms of the input of Estimator 203, y(n), is defined as:

$$z ( n ) = {\sum }_{p = 0}^{P} {\sum }_{q = 0}^{Q} {a}_{pq} {ϕ}_{pq} [ \frac{y ( n )}{G} ] \qquad ( 5 )$$

where

$$[ \frac{y ( n )}{G} ]$$

is the output of PA 117 normalized by the desired gain G of the Power Amplifier, representing the corresponding input if the PA 117 were acting linearly.

The memory effects are incorporated by the memory depth P and nonlinearity order Q of PA 117, respectively. Here a_{pq} is the set of constants we′d like to find optimally for the best fitting model and to get the corresponding the output values z(n). Note that

$${ϕ}_{p q} [ \frac{y ( n )}{G} ] = \frac{y ( n - p )}{G} \vert \frac{y ( n - p )}{G} ) {\vert}^{q} \qquad ( 6 )$$

which is computed for each value where p∈[0,P], q∈[0, Q].

Assuming N samples of PA output y(n) are measured, lets generate the input vector z with dimensions N×1 (viz. N rows and 1 column):

z=[z(1),z(2), . . . ,z(N)]^{T} (7)

Rewriting Eq. (5) in vector form:

z=Y a (8)

where

a=[a₀₀, . . . ,a_{0Q},a₁₀, . . . ,a_{1Q}, . . . ,a_{P0}, . . . ,a_{PQ}]^{T} (9a)

a is a vector of size [P×Q]×1 with elements a_{pq} where p∈[0, P], q∈[0, Q].

where the Y matrix of size Nx[PxQ] is:

$$\begin{matrix}Y = [ {u}_{00} , … , {u}_{0 Q} , {u}_{10} , … , {u}_{1 Q} , … , {u}_{P 0} , … , {u}_{PQ} ] & ( 9 b ) \\ {u}_{pq} = [ {ϕ}_{p q} [ \frac{y ( 1 )}{G} ] , {ϕ}_{p q} [ \frac{y ( 2 )}{G} ] , … , {{ϕ}_{pq} [ \frac{y ( N )}{G} ]}^{T} & ( 10 )\end{matrix}$$

The coefficients of Estimator 203 are found as follows:

Ya=z (same as Eq. (5))

(Y^{H}Y)â=Y^{H}z (11)

â=(Y^{H}Y)⁻¹Y^{H}z (12)

where

a=[a₀₀, . . . ,a_{0Q},a₁₀, . . . ,a_{1Q}, . . . ,a_{P0}, . . . ,a_{PQ}]^{T} (9a)

â is the solution vector of size [P×Q]×1 with elements a_{pq} where p∈[0, P], q∈[0, Q]. â and corresponding z are found iteratively by minimizing the error between the linear fit to the actual measured output, using methods known in prior art.

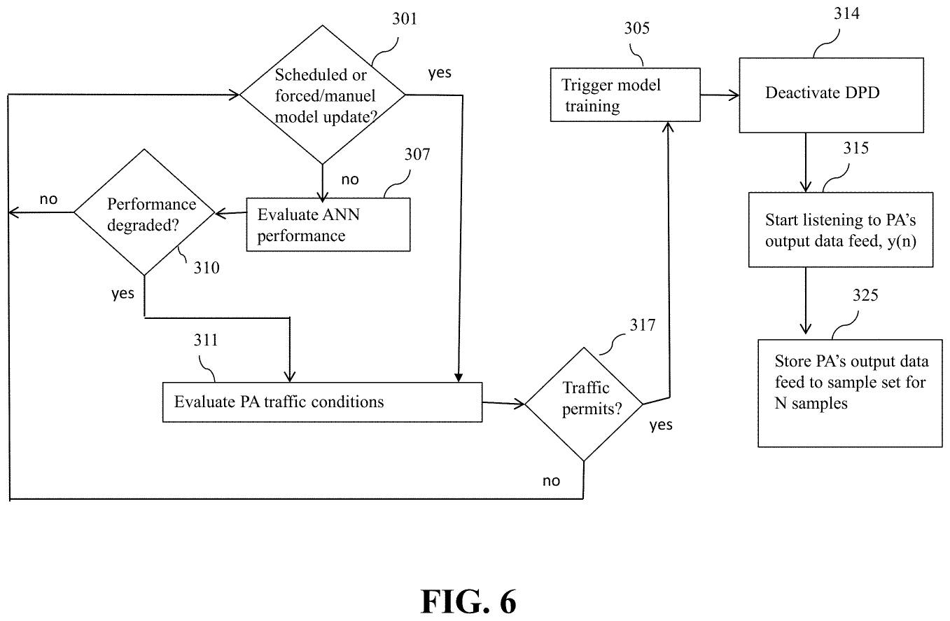

The first method of the present invention, depicted in FIG. 6, initiates a model training cycle by Training Session Activator 241. The process starts at step 301, wherein Trainer Session Activator 241 checks to determine, if it is time for a scheduled (periodic) update or for a manual (forced) model update. If yes, it goes to step 311 to first evaluate the traffic load on the PA. If traffic is very heavy, in check-point 317, it returns back to 301, to wait for the proper time. Note that at times of the day when the RF transmitter is too busy with traffic, it may not be advisable to take the DPD out of commission simply to collect training data. Otherwise, at check-point 317, it triggers the model update in step 305. This step reinitiates a model-training phase by (a) first deactivating the DPD in step 314 and (b) start listening the PA's output data y(n) without any effects of pre-distorter. Subsequently, in step 325, the system stores N samples in the memory of the Training System 200 where N is configurable. If it is not a prescheduled update, the system evaluates the ANN performance in step 307, and if the performance is degraded, according to check-point 310, it returns to step 311, Otherwise, it waits for the next scheduled training cycle. The process 307 evaluates the ANN performance by comparing the input and output samples for linearity and interference, and checks to determine if the ANN performance is below an EVM threshold over a specified time period. Otherwise, it evaluates conditions such as temperature, bandwidth and frequency usage, etc. in step 307 using output samples, and checks to determine if there is a major change. If yes, it returns to step 311, looking for a good start-time when traffic load is less. These check-points may be implemented in a different sequence order, or there may be other check-points added, or some mentioned check-points may not be implemented in Training Session Activator 241.

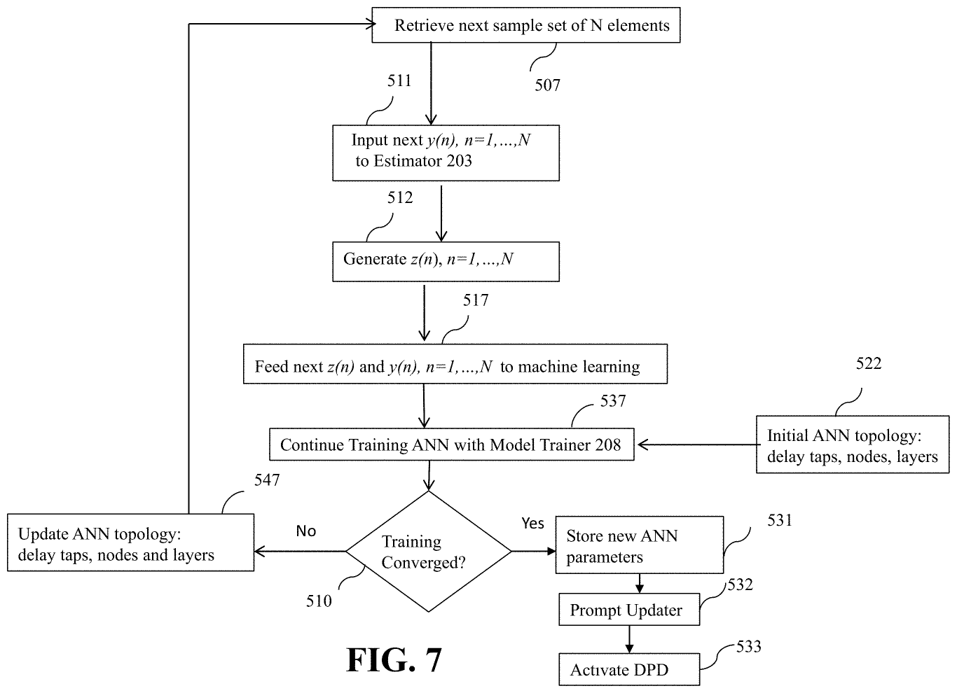

The second method of the present invention is depicted in FIG. 7 to perform the model training using ANN Model Trainer 208 and Estimator 203. Once Training Session Activator 241 triggers a model training phase, then the system of the present invention starts feeding y(n) stored in memory into Estimator 203 in step 511, upon which it generates best fitting z(n) in step 512. The pair of y(n) and z(n), n=1, 2, . . . , N are then fed into 208's machine training algorithm as input and output data samples in step 517. During the continued training in step 537, an initial topology in step 522 is assumed. If training converges, Updater 248 is prompted in step 532. Upon prompting, Updater 248 loads the new parameters to DPD 201b, and activates it at step 533 using ANN Activator/Deactivator 249. Otherwise, the previous topology is extended in step 547, and the process returns to the first step of learning.

In one embodiment, the present invention provides a method for adaptive model training of a pre-distorter (PD), the PD configured to pre-distort a power amplifier (PA) input signal of a power amplifier (PA) for a compensation of non-linear behavior and memory effects of the power amplifier, the compensation causing a power amplifier (PA) output signal of the PA to become linearly related to a pre-distorter (PD) input signal and exhibit only a constant delay over time, the method comprising the steps of: (a) identifying an initial topology of an artificial neural network (ANN) model stored in an ANN model trainer, the initial topology comprising: (1) number of neurons in the ANN, (2) number of layers of the ANN, and (3) number of delay taps of the ANN, wherein each delay tap represents one sample delay and a total number of delay taps defining a memory depth of the power amplifier; (b) entering the PA output signal without predistortion as an estimator input signal into an estimator, the estimator configured to use a regression technique and a memory effect modeling technique and generate an estimator output signal corresponding to a best polynomial fit to the estimator input signal; (c) training the ANN model stored in the ANN model trainer using a machine learning algorithm utilizing the PA output signal obtained without predistortion as the ANN model trainer's input and the estimator output signal as the ANN model trainer's output until convergence where the PA output signal obtained with predistortion according to ANN model stored exhibiting a linear relation to the PA input signal with a constant delay, and when convergence is not reached, changing the initial topology and repeating steps (a) through (c) until convergence is reached, and when convergence is reached, mapping parameters corresponding to topology changes as another ANN used in the PD.

In another embodiment, the present invention provides a system comprising: (a) a pre-distorter (PD), the PD configured to pre-distort a power amplifier (PA) input signal of a power amplifier (PA) for a compensation of non-linear behavior and memory effects of the power amplifier, the compensation causing a power amplifier (PA) output signal of the PA to become linearly related to a pre-distorter (PD) input signal and exhibit only a constant delay over time; (b) an ANN model trainer, the ANN model trainer storing an artificial neural network (ANN) model, wherein an initial topology of the ANN model comprising: (1) number of neurons in the ANN, (2) number of layers of the ANN, and (3) number of delay taps of the ANN, wherein each delay tap represents one sample delay and a total number of delay taps defining a memory depth of the power amplifier; wherein the PA output signal without predistortion is input as an estimator input signal into an estimator, the estimator configured to use a regression technique and a memory effect modeling technique and generate an estimator output signal corresponding to a best polynomial fit to the estimator input signal; and the ANN model stored in the ANN model trainer is trained using a machine learning algorithm utilizing the PA output signal obtained without predistortion as the ANN model trainer's input and the estimator output signal as the ANN model trainer's output until convergence where the PA output signal obtained with predistortion according to ANN model stored exhibiting a linear relation to the PA input signal with a constant delay, and when convergence is not reached, the initial topology being changed until convergence is reached, and when convergence is reached, mapping parameters corresponding to topology changes as another ANN used in the PD.

In yet another embodiment, the present invention provides a non-transitory, computer accessible, memory medium storing program instructions for implementing a method for adaptive model training of a pre-distorter (PD), the PD configured to pre-distort a power amplifier (PA) input signal of a power amplifier (PA) for a compensation of non-linear behavior and memory effects of the power amplifier, the compensation causing a power amplifier (PA) output signal of the PA to become linearly related to a pre-distorter (PD) input signal and exhibit only a constant delay over time, wherein one or more programs are stored in the memory and configured to be executed by the one or more processors, the medium comprising: (a) computer readable program identifying an initial topology of an artificial neural network (ANN) model stored in an ANN model trainer, the initial topology comprising: (1) number of neurons in the ANN, (2) number of layers of the ANN, and (3) number of delay taps of the ANN, wherein each delay tap represents one sample delay and a total number of delay taps defining a memory depth of the power amplifier; (b) computer readable program entering the PA output signal without predistortion as an estimator input signal into an estimator, the estimator configured to use a regression technique and a memory effect modeling technique and generate an estimator output signal corresponding to a best polynomial fit to the estimator input signal; and (d) computer readable program training the ANN model stored in the ANN model trainer using a machine learning algorithm utilizing the PA output signal obtained without predistortion as the ANN model trainer's input and the estimator output signal as the ANN model trainer's output until convergence where the PA output signal obtained with predistortion according to ANN model stored exhibiting a linear relation to the PA input signal with a constant delay, and when convergence is not reached, changing the initial topology and repeating steps (a) through (c) until convergence is reached, and when convergence is reached, mapping parameters corresponding to topology changes as another ANN used in the PD.

The above-described features and applications can be implemented as software processes that are specified as a set of instructions recorded on a computer readable storage medium (also referred to as computer readable medium). When these instructions are executed by one or more processing unit(s) (e.g., one or more processors, cores of processors, or other processing units), they cause the processing unit(s) to perform the actions indicated in the instructions. Embodiments within the scope of the present disclosure may also include tangible and/or non-transitory computer-readable storage media for carrying or having computer-executable instructions or data structures stored thereon. Such non-transitory computer-readable storage media can be any available media that can be accessed by a general purpose or special purpose computer, including the functional design of any special purpose processor. By way of example, and not limitation, such non-transitory computer-readable media can include flash memory, RAM, ROM, EEPROM, CD-ROM or other optical disk storage, magnetic disk storage or other magnetic storage devices, or any other medium which can be used to carry or store desired program code means in the form of computer-executable instructions, data structures, or processor chip design. The computer readable media does not include carrier waves and electronic signals passing wirelessly or over wired connections.

Computer-executable instructions include, for example, instructions and data which cause a general purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing or executing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few.

In this specification, the term “software” is meant to include firmware residing in read-only memory or applications stored in magnetic storage or flash storage, for example, a solid-state drive, which can be read into memory for processing by a processor. Also, in some implementations, multiple software technologies can be implemented as sub-parts of a larger program while remaining distinct software technologies. In some implementations, multiple software technologies can also be implemented as separate programs. Finally, any combination of separate programs that together implement a software technology described here is within the scope of the subject technology. In some implementations, the software programs, when installed to operate on one or more electronic systems, define one or more specific machine implementations that execute and perform the operations of the software programs.

A computer program (also known as a program, software, software application, to script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

These functions described above can be implemented in digital electronic circuitry, in computer software, firmware or hardware. The techniques can be implemented using one or more computer program products. Programmable processors and computers can be included in or packaged as mobile devices. The processes and logic flows can be performed by one or more programmable processors and by one or more programmable logic circuitry. General and special purpose computing devices and storage devices can be interconnected through communication networks.

Some implementations include electronic components, for example microprocessors, storage and memory that store computer program instructions in a machine-readable or computer-readable medium (alternatively referred to as computer-readable storage media, machine-readable media, or machine-readable storage media). Some examples of such computer-readable media include RAM, ROM, read-only compact discs (CD-ROM), recordable compact discs (CD-R), rewritable compact discs (CD-RW), read-only digital versatile discs (e.g., DVD-ROM, dual-layer DVD-ROM), a variety of recordable/rewritable DVDs (e.g., DVD-RAM, DVD-RW, DVD+RW, etc.), flash memory (e.g., SD cards, mini-SD cards, micro-SD cards, etc.), magnetic or solid state hard drives, read-only and recordable Blu-Ray® discs, ultra density optical discs, any other optical or magnetic media, and floppy disks. The computer-readable media can store a computer program that is executable by at least one processing unit and includes sets of instructions for performing various operations. Examples of computer programs or computer code include machine code, for example is produced by a compiler, and files including higher-level code that are executed by a computer, an electronic component, or a microprocessor using an interpreter.

While the above discussion primarily refers to microprocessor or multi-core processors that execute software, some implementations are performed by one or more integrated circuits, for example application specific integrated circuits (ASICs) or field programmable gate arrays (FPGAs). In some implementations, such integrated circuits execute instructions that are stored on the circuit itself.

As used in this specification and any claims of this application, the terms “computer”, “server”, “processor”, and “memory” all refer to electronic or other technological devices. These terms exclude people or groups of people. For the purposes of the specification, the terms display or displaying means displaying on an electronic device. As used in this specification and any claims of this application, the terms “computer readable medium” and “computer readable media” are entirely restricted to tangible, physical objects that store information in a form that is readable by a computer. These terms exclude any wireless signals, wired download signals, and any other ephemeral signals.

To provide for interaction with a user, implementations of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

The subject matter described in this specification can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

Those of skill in the art will appreciate that other embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

The computing system can include clients and servers. A client and server are generally remote from each other and typically interact through a communication network. The relationship of client and server arises by virtue of computer programs running on the respective computers and having a client-server relationship to each other. In some aspects of the disclosed subject matter, a server transmits data (e.g., an HTML page) to a client device (e.g., for purposes of displaying data to and receiving user input from a user interacting with the client device). Data generated at the client device (e.g., a result of the user interaction) can be received from the client device at the server.

It is understood that any specific order or hierarchy of steps in the processes disclosed is an illustration of example approaches. Based upon design preferences, it is understood that the specific order or hierarchy of steps in the processes may be rearranged, or that all illustrated steps be performed. Some of the steps may be performed simultaneously. For example, in certain circumstances, multitasking and parallel processing may be advantageous. Moreover, the separation of various system components illustrated above should not be understood as requiring such separation, and it should be understood that the described program components and systems can generally be integrated together in a single software product or packaged into multiple software products.

Various modifications to these aspects will be readily apparent, and the generic principles defined herein may be applied to other aspects. Thus, the claims are not intended to be limited to the aspects shown herein, but is to be accorded the full scope consistent with the language claims, where reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject technology.

A phrase, for example, an “aspect” does not imply that the aspect is essential to the subject technology or that the aspect applies to all configurations of the subject technology.

A disclosure relating to an aspect may apply to all configurations, or one or more configurations. A phrase, for example, an aspect may refer to one or more aspects and vice versa. A phrase, for example, a “configuration” does not imply that such configuration is essential to the subject technology or that such configuration applies to all configurations to of the subject technology. A disclosure relating to a configuration may apply to all configurations, or one or more configurations. A phrase, for example, a configuration may refer to one or more configurations and vice versa.

The various embodiments described above are provided by way of illustration only and should not be construed to limit the scope of the disclosure. Those skilled in the art will readily recognize various modifications and changes that may be made to the principles described herein without following the example embodiments and applications illustrated and described herein, and without departing from the spirit and scope of the disclosure.

While this specification contains many specific implementation details, these should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one to or more features from a claimed combination can in some cases be excised from the combination, and the claimed combination may be directed to a subcombination or variation of a sub combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

As noted above, particular embodiments of the subject matter have been described, but other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous.

### CONCLUSION

A system and method have been shown in the above embodiments for the effective implementation of a system, method and article of manufacture for model trainer for digital pre-distorter of power amplifiers. While various preferred embodiments have been shown and described, it will be understood that there is no intent to limit the invention by such disclosure, but rather, it is intended to cover all modifications falling within the spirit and scope of the invention, as defined in the appended claims.

1. A method for adaptive model training of a pre-distorter (PD), the PD configured to pre-distort a power amplifier (PA) input signal of a power amplifier (PA) for a compensation of non-linear behavior and memory effects of the power amplifier, the compensation causing a power amplifier (PA) output signal of the PA to become linearly related to a pre-distorter (PD) input signal and exhibit only a constant delay over time, the method comprising the steps of:
(a) identifying an initial topology of an artificial neural network (ANN) model stored in an ANN model trainer, the initial topology comprising: (1) number of neurons in the ANN, (2) number of layers of the ANN, and (3) number of delay taps of the ANN, wherein each delay tap represents one sample delay and a total number of delay taps defining a memory depth of the power amplifier;
(b) entering the PA output signal without predistortion as an estimator input signal into an estimator, the estimator configured to use a regression technique and a memory effect modeling technique and generate an estimator output signal corresponding to a best polynomial fit to the estimator input signal;
(c) training the ANN model stored in the ANN model trainer using a machine learning algorithm utilizing the PA output signal obtained without predistortion as the ANN model trainer's input and the estimator output signal as the ANN model trainer's output until convergence where the PA output signal obtained with predistortion according to ANN model stored exhibiting a linear relation to the PA input signal with a constant delay, and when convergence is not reached, changing the initial topology and repeating steps (a) through (c) until convergence is reached, and when convergence is reached, mapping parameters corresponding to topology changes as another ANN used in the PD.

2. The method of claim 1, wherein the estimator uses an Ordinary Least Square (OLS), Recursive Least Square (RLS) or Least Mean Square (LMS) algorithm.

3. The method of claim 1, wherein the memory effect modelling technique is picked from any of the following: models memory effects using Volterra series, or Memory Polynomials, or Weiner model, and Hammerstein model.

4. The method of claim 1, wherein the machine learning algorithm is a deep learning algorithm.

5. The method of claim 1, wherein the PA is implemented in a radio frequency (RF) transmitter of a base station (BS) in a cellular network.

6. The method of claim 1, wherein the PA input and PA output signals are baseband discreet time samples with in-phase and quadrature components.

7. The method of claim 6, wherein the ANN model trainer provides separate neural pathway for the in-phase and quadrature components.

8. The method of claim 1, wherein the PA input and PA output signals are radio frequency (RF) signals.

9. The method of claim 1, wherein the method further comprises the step of triggering model training cycle of the PD that is previously trained, wherein the step of triggering model training cycle further comprises the steps of:
(a) capturing the PA input signal and PA output signal of PA; and
(b) initiating a model training cycle for the ANN model when any of the following is determined: (1) when there is a manual request for the model training cycle, (2) when there is a schedule-based request, (3) when there is an expiration of a timer associated with retraining, (4) when the PA violates a performance threshold determined by using data obtained in step (a), and (5) when operations conditions of the PA have changed.

10. A system comprising:
(a) a pre-distorter (PD), the PD configured to pre-distort a power amplifier (PA) input signal of a power amplifier (PA) for a compensation of non-linear behavior and memory effects of the power amplifier, the compensation causing a power amplifier (PA) output signal of the PA to become linearly related to a pre-distorter (PD) input signal and exhibit only a constant delay over time;
(b) an ANN model trainer, the ANN model trainer storing an artificial neural network (ANN) model, wherein an initial topology of the ANN model comprising: (1) number of neurons in the ANN, (2) number of layers of the ANN, and (3) number of delay taps of the ANN, wherein each delay tap represents one sample delay and a total number of delay taps defining a memory depth of the power amplifier;
wherein the PA output signal without predistortion is input as an estimator input signal into an estimator, the estimator configured to use a regression technique and a memory effect modeling technique and generate an estimator output signal corresponding to a best polynomial fit to the estimator input signal; and
the ANN model stored in the ANN model trainer is trained using a machine learning algorithm utilizing the PA output signal obtained without predistortion as the ANN model trainer's input and the estimator output signal as the ANN model trainer's output until convergence where the PA output signal obtained with predistortion according to ANN model stored exhibiting a linear relation to the PA input signal with a constant delay, and when convergence is not reached, the initial topology being changed until convergence is reached, and when convergence is reached, mapping parameters corresponding to topology changes as another ANN used in the PD.

11. The system of claim 10, wherein the estimator uses an Ordinary Least Square (OLS), Recursive Least Square (RLS) or Least Mean Square (LMS) algorithm.

12. The system of claim 10, wherein the memory effect modelling technique is picked from any of the following: models memory effects using Volterra series, or Memory Polynomials, or Weiner model, and Hammerstein model.

13. The system of claim 10, wherein the machine learning algorithm is a deep learning algorithm.

14. The system of claim 10, wherein the PA is implemented in a radio frequency (RF) transmitter of a base station (BS) in a cellular network.

15. The system of claim 10, wherein the PA input and PA output signals are baseband discreet time samples with in-phase and quadrature components.

16. The system of claim 15, wherein the ANN model trainer provides separate neural pathway for the in-phase and quadrature components.

17. The system of claim 10, wherein the PA input and PA output signals are radio frequency (RF) signals.

18. The system of claim 10, wherein the system further comprises a training session activator for activating training and an ANN Activator/Deactivator for activating/deactivating the PD, wherein the training session activator and the ANN Activator/Deactivator are used in triggering model training cycle of the PD that is previously trained based on:
(a) capturing the PA input signal and PA output signal of PA; and
(b) initiating a model training cycle for the ANN model when any of the following is determined: (1) when there is a manual request for the model training cycle, (2) when there is a schedule-based request, (3) when there is an expiration of a timer associated with retraining, (4) when the PA violates a performance threshold determined by using data obtained in step (a), and (5) when operations conditions of the PA have changed.

19. A non-transitory, computer accessible, memory medium storing program instructions for implementing a method for adaptive model training of a pre-distorter (PD), the PD configured to pre-distort a power amplifier (PA) input signal of a power amplifier (PA) for a compensation of non-linear behavior and memory effects of the power amplifier, the compensation causing a power amplifier (PA) output signal of the PA to become linearly related to a pre-distorter (PD) input signal and exhibit only a constant delay over time, wherein one or more programs are stored in the memory and configured to be executed by the one or more processors, the medium comprising:
(a) computer readable program identifying an initial topology of an artificial neural network (ANN) model stored in an ANN model trainer, the initial topology comprising: (1) number of neurons in the ANN, (2) number of layers of the ANN, and (3) number of delay taps of the ANN, wherein each delay tap represents one sample delay and a total number of delay taps defining a memory depth of the power amplifier;
(b) computer readable program entering the PA output signal without predistortion as an estimator input signal into an estimator, the estimator configured to use a regression technique and a memory effect modeling technique and generate an estimator output signal corresponding to a best polynomial fit to the estimator input signal; and
(d) computer readable program training the ANN model stored in the ANN model trainer using a machine learning algorithm utilizing the PA output signal obtained without predistortion as the ANN model trainer's input and the estimator output signal as the ANN model trainer's output until convergence where the PA output signal obtained with predistortion according to ANN model stored exhibiting a linear relation to the PA input signal with a constant delay, and when convergence is not reached, changing the initial topology and repeating steps (a) through (c) until convergence is reached, and when convergence is reached, mapping parameters corresponding to topology changes as another ANN used in the PD.
